(19) United States
(12) Patent Application Publication
(10) Pub. No.: US 2019/0236922 A1
(43) Pub. Date: Aug. 1, 2019

(54) Optical Cabin and Cargo Smoke Detection Using Multiple Spectrum Light

(71) Applicant: The Boeing Company, Chicago, IL (US)

(72) Inventors: Donald B. Lee, Shoreline, WA (US); Scott W. McGilton, Redmond, WA (US)

(21) Appl. No.: 15/883,411

(22) Filed: Jan. 30, 2018

(51) Int. Cl. G08B 17/12; A62C 3/08; G08B 7/00; H05K 1/02; G06T 11/00

(52) U.S. Cl. CPC G08B 17/125; A62C 3/08; G06T 11/00; H05K 1/0275; G08B 7/00

(57) ABSTRACT

The disclosed fire detection system improves fire detection, e.g., aboard an aircraft, by optically monitoring an interior compartment to detect, at a first time, visible radiation in a visible light spectrum and thermal radiation in an infrared light spectrum. The fire detection system combines the detected radiation to generate a multi-spectrum image, spanning visible and infrared wavelengths, of the interior compartment at the first time to facilitate the detection of a fire event and/or threat within the interior compartment. As a result, the fire detection system provides situational awareness of a fire event and/or threat within the interior compartment.

### TECHNICAL FIELD

The present disclosure generally relates to fire detection, and more particularly relates to visual fire detection for interior compartments.

### BACKGROUND

Aircraft typically employ smoke detection systems to notify pilots, crew, and/or ground support of a fire onboard the aircraft. Known smoke detection systems provide a binary indication of the presence or absence of smoke in the vicinity of the smoke detector; they do not provide any information regarding the amount of smoke, the precise location of the smoke, or the severity of any associated fire. Further, depending on the location of the smoke detection system relative to a fire, there may be a delay in the detection of any smoke resulting from such a fire by a smoke detection system. Further, smoke detection systems have no ability to detect a fire risk, e.g., due to high heat, because such high temperatures do not necessarily produce smoke.

### SUMMARY

The present disclosure relates to methods, apparatuses, systems, computer program products, software, and/or mediums for improved fire detection. To that end, aspects presented herein generate a multi-spectrum image, spanning visible and infrared wavelengths, of an interior compartment to facilitate fire detection within the interior compartment. As a result, aspects presented herein provide an operator monitoring the interior compartment with situational awareness of a fire threat within the interior compartment, and potentially alerts the operator to a fire event or threat sooner than smoke detection systems.

According to the present disclosure, a fire detection system comprises image sensor circuitry and processor circuitry, which collectively are configured to generate a multi-spectrum image of an interior compartment to facilitate fire detection within the interior compartment. The image sensor circuitry is configured to optically monitor the interior compartment to detect visible radiation within a visible light spectrum at a first time and thermal radiation within an infrared light spectrum at the first time. As used herein, “first time” can refer to an instant of time (e.g., for a still image) or a period of time (e.g., for a sequence of images or video). The processor circuitry is operatively connected to the image sensor circuitry and is configured to generate the multi-spectrum image of the interior compartment at the first time by combining the detected visible radiation with the detected thermal radiation. The processor circuitry is further configured to output the multi-spectrum image to at least one operator terminal communicatively coupled to the processor circuitry.

According to a further aspect, the image sensor circuitry comprises a first image sensor configured to operate in at least the visible light spectrum and a second image sensor configured to operate in the infrared light spectrum.

According to a further aspect, the first image sensor comprises a pinhole image sensor and the second image sensor comprises a forward looking infrared image sensor. The pinhole image sensor and the forward looking infrared image sensor are disposed on a first side of a printed circuit board, and the processor circuitry are disposed on a second side of the printed circuit board, said first and second sides on opposing sides of the printed circuit board.

According to a further aspect, the first image sensor is further configured to detect additional thermal radiation within an additional infrared light spectrum in combination with the visible radiation within the visible light spectrum. The processor circuitry generates the multi-spectrum image by combining the detected thermal radiation output by the second image sensor with the detected visible radiation in combination with the additional thermal radiation output by the first image sensor.

According to a further aspect, the interior compartment is comprised within an aircraft, and the at least one operator terminal is comprised within a cockpit of the aircraft.

According to a further aspect, the aircraft is in wireless communication with a ground station, and the processor circuitry is further configured to output the multi-spectrum image by transmitting the multi-spectrum image to an operator terminal in the ground station.

According to a further aspect, the processor circuitry is further configured to process the multi-spectrum image to determine a fire status of the interior compartment. Upon detection of a fire event within the interior compartment responsive to the processing of the multi-spectrum image, the processor circuitry is configured to output at least one of a visible alarm and an audio alarm to the at least one operator terminal.

According to a further aspect, the processor circuitry is further configured to output at least one of the detected visible radiation and the detected thermal radiation to the at least one operator terminal.

According to a further aspect, the visible radiation and the thermal radiation each comprise a still image of the corresponding radiation or a video of the corresponding radiation.

According to a further aspect, the visible light spectrum includes at least wavelengths ranging between 400 nm and 700 nm, and the infrared light spectrum includes at least wavelengths ranging between 8,000 nm and 14,000 nm.

According to the present disclosure, a method of generating a multi-spectrum image of an interior compartment for fire detection within the interior compartment is disclosed. The method comprises optically monitoring the interior compartment using image sensor circuitry to detect visible radiation within a visible light spectrum at a first time and thermal radiation within an infrared light spectrum at the first time. The method further comprises generating the multi-spectrum image of the interior compartment at the first time by combining the detected visible radiation with the detected thermal radiation, and outputting the multi-spectrum image to at least one operator terminal.

According to a further aspect, the image sensor circuitry comprises a first image sensor configured to operate in at least the visible light spectrum and a second image sensor configured to operate in the infrared light spectrum, where optically monitoring the interior compartment using the image sensor circuitry comprises optically monitoring the interior compartment using the first and second image sensors to detect, at the first time, the visible radiation within the visible light spectrum and the thermal radiation within the infrared light spectrum, respectively, of the interior compartment.

According to a further aspect, the first image sensor comprises a pinhole image sensor and the second image sensor comprises a forward looking infrared image sensor.

According to a further aspect, detecting, using the first image sensor, additional thermal radiation within an additional infrared light spectrum in combination with the visible radiation within the visible light spectrum, where generating the multi-spectrum image comprises combining the detected thermal radiation output by the second image sensor with the detected visible radiation in combination with the additional thermal radiation output by the first image sensor.

According to a further aspect, the interior compartment is comprised within an aircraft, and the at least one operator terminal is comprised within a cockpit of the aircraft.

According to a further aspect, the aircraft is in wireless communication with a ground station, where outputting the multi-spectrum signal to the at least one operator terminal further comprises transmitting the multi-spectrum image to an operator terminal in the ground station.

According to a further aspect, processing the multi-spectrum image to determine a fire status of the interior compartment, and upon detection of a fire event within the interior compartment responsive to the processing of the multi-spectrum image, outputting at least one of a visible alarm and an audio alarm to the at least one operator terminal.

According to a further aspect, outputting at least one of the detected visible radiation and the detected thermal radiation to the at least one operator terminal.

According to a further aspect, the visible light spectrum includes at least wavelengths ranging between 400 nm and 700 nm, and the infrared light spectrum includes at least wavelengths ranging between 8,000 nm and 14,000 nm.

According to the present disclosure a non-transitory computer readable medium storing a computer program product for controlling a programmable fire detection system to generate a multi-spectrum image of an interior compartment to facilitate fire detection within the interior compartment is disclosed. The computer program product comprises software instruction that, when executed on processor circuitry of the programmable fire detection system, causes the processor circuitry to optically monitor the interior compartment using image sensor circuitry to detect visible radiation within a visible light spectrum at a first time and thermal radiation within an infrared light spectrum at the first time, generate the multi-spectrum image of the interior compartment at the first time by combining the detected visible radiation with the detected thermal radiation, and output the multi-spectrum image to at least one operator terminal.

### BRIEF DESCRIPTION OF THE DRAWINGS

Aspects of the present disclosure are illustrated by way of example and are not limited by the accompanying figures with like references indicating like elements. In general, the use of a reference numeral should be regarded as referring to the depicted subject matter generally, whereas discussion of a specific instance of an illustrated element will append a letter designation thereto (e.g., discussion of an image sensor circuitry 122, generally, as opposed to discussion of particular examples of individual image sensors 122a, 122b).

FIG. 1 shows a block diagram illustrating an example network environment, according to an aspect of the present disclosure.

FIG. 2 shows a partial cutaway side view of an exemplary aircraft, according to an aspect of the present disclosure.

FIG. 3 shows a flow diagram of an exemplary method, according to an aspect of the present disclosure.

FIG. 4 shows electromagnetic spectrum applicable to aspects of the present disclosure.

FIG. 5 shows exemplary operator terminals relative to the fire detection system, according to aspects of the present disclosure.

FIG. 6A shows an exemplary printed circuit board implementation of the image sensor and processor circuitry of the fire detection system, according to an aspect of the present disclosure.

FIG. 6B shows an exemplary camera board stack-up of the image sensor and processor circuitry of the fire detection system, according to an aspect of the present disclosure.

FIG. 7 shows a block diagram of an exemplary fire detection system, according to an aspect of the present disclosure.

### DETAILED DESCRIPTION

Aspects of the present disclosure are directed to methods, apparatuses, systems, computer program products, and/or software for fire detection within an interior compartment, e.g., an interior compartment of an aircraft. Traditional aircraft fire detection systems comprise smoke detectors that do not provide information regarding the precise location or size of a fire, do not always provide timely detection, e.g., when the fire is remote from the nearest smoke detector, and do not provide early alerts for potential fire threats, e.g., due to high temperatures. According to aspects of the present disclosure, a multi-spectrum fire detection system addresses one or more shortcomings of traditional smoke detection systems by, among other things, optically monitoring multiple radiation spectrums of the interior compartment to provide a multi-spectrum image of the interior compartment.

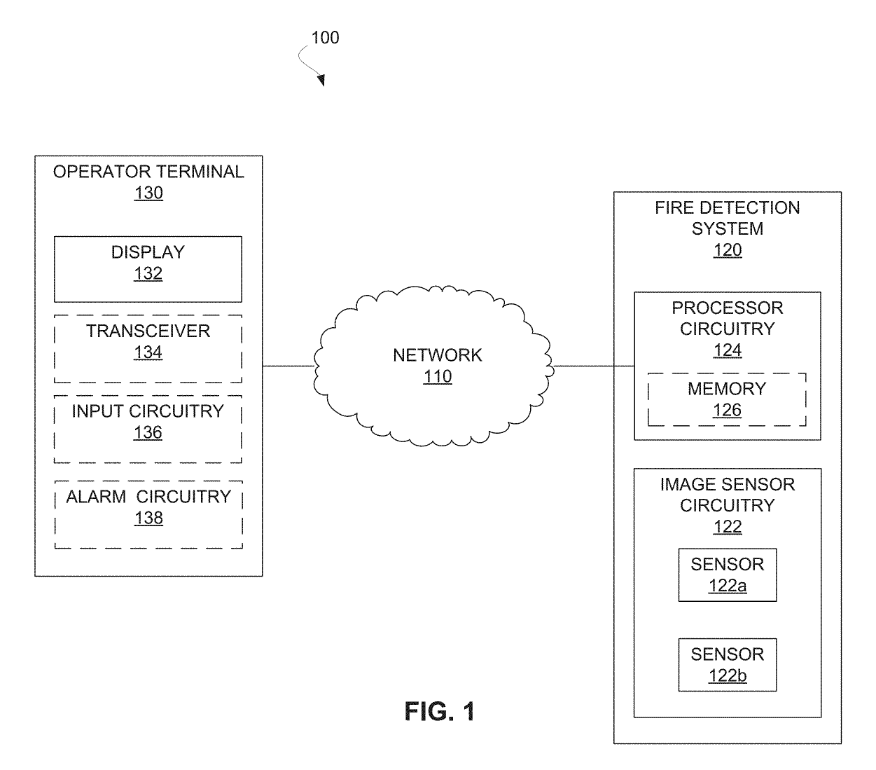

FIG. 1 shows an exemplary network environment 100, according to an aspect of the disclosure, comprising a fire detection system 120 and an operator terminal 130 communicatively connected to each other via a network 110. The network 110 includes one or more physical devices and/or signaling mediums capable of exchanging communication signals between the fire detection system 120 and the operator terminal 130. Examples of such a network 110 include (but are not limited to) one or more signaling mediums; one or more local area networks; one or more wireless networks; one or more Internet Protocol-based networks; one or more Ethernet networks; one or more optical networks; one or more ad hoc networks; and/or one or more electrical buses. Such a network 110 can comprise any number of networking devices such as routers, gateways, switches, hubs, firewalls, multiplexers, controllers, and the like (not shown) supporting the exchange of such communication signals. While FIG. 1 shows one fire detection system 120 communicatively connected to one operator terminal 130 via network 110, it will be appreciated that network 110 can communicatively connect any number of fire detection systems 120 to any number of operator terminals 130.

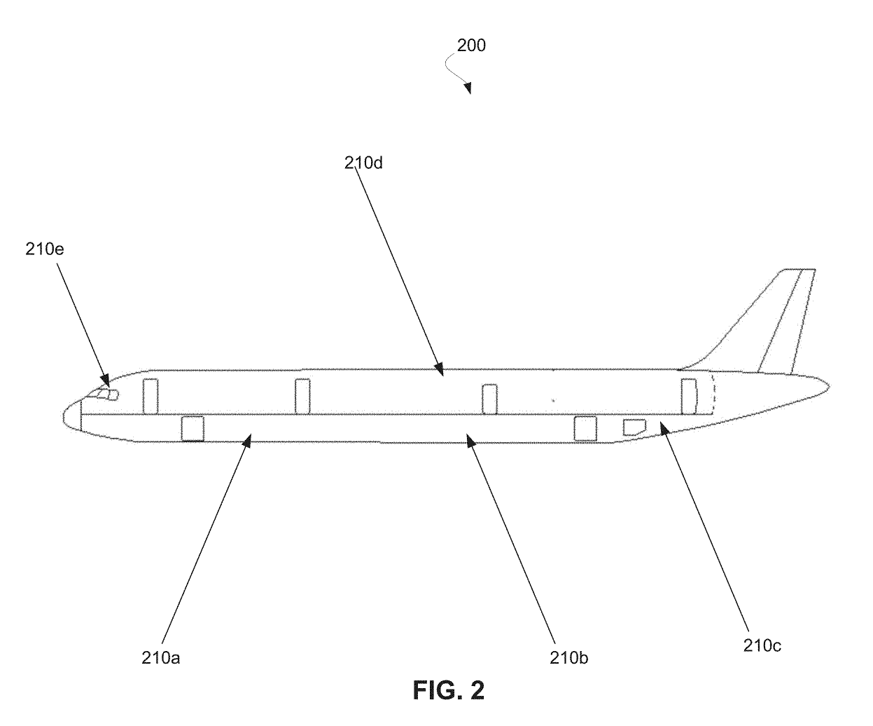

Fire detection system 120 comprises image sensor circuitry 122 and processor circuitry 124 that cooperatively monitor an interior compartment 210 for a fire threat or fire event. FIG. 2 shows a partial cutaway side view of an aircraft 200 to show exemplary interior compartments 210 for an aircraft 200, which include, but are not limited to, the forward cargo hold 210a, aft cargo hold 210b, rear cargo hold 210c, restroom (not shown), passenger compartment 210d, galley (not shown), cockpit 210e, etc. It will be appreciated that the fire detection system 120 presented herein can also monitor other interior compartments 210 not part of an aircraft 200, including but not limited to, interior compartments 210 of ground control stations, factories, manufacturing plants, ground-based surveillance systems, airports, etc. For simplicity, reference number 210 is used herein to generally refer to any interior compartment 210 applicable for the fire detection system 120 disclosed herein.

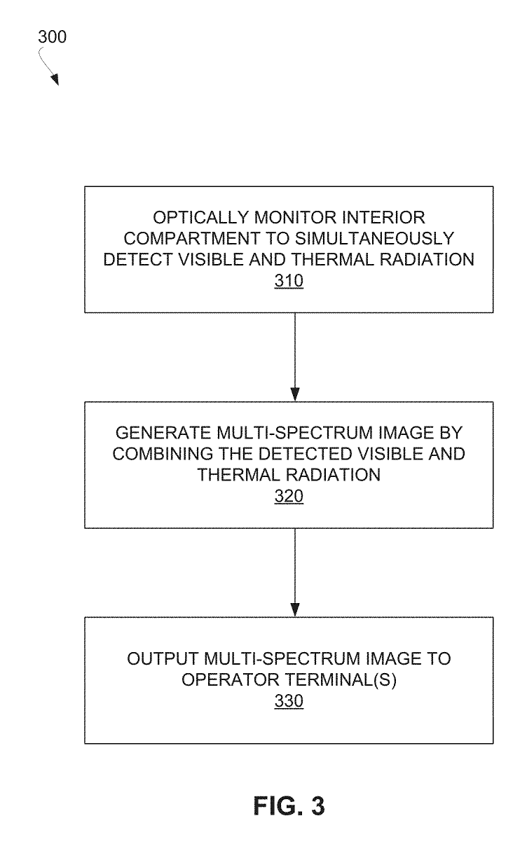

According to various aspects, fire detection system 120 implements the method 300 shown in FIG. 3. According to method 300, the fire detection system 120 optically monitors the interior compartment 210 to detect, at a first time, visible radiation within a visible light spectrum and thermal radiation within an infrared light spectrum (block 310). As used herein, “first time” can refer to an instant of time (e.g., for a still image) or a period of time (e.g., for a sequence of images or video). The fire detection system 120 further combines the detected visible radiation with the detected thermal radiation to generate a multi-spectrum image of the interior compartment 210 at the first time (block 320), and outputs the multi-spectrum image to at least one operator terminal 130 (block 330).

In some aspects, the multi-spectrum image comprises a still image of the interior compartment 210, representing a combination of time-aligned still images of the visible and infrared radiation in the interior compartment 210 at a single moment in time, e.g., still images of the visible and infrared radiation detected at the same time. In other aspects, the multi-spectrum image comprises a multi-spectrum video of the interior compartment 210, representing a time-aligned combination of a video of the visible and infrared radiation in the interior compartment 210 over the same period of time. In any event, the multi-spectrum image enables an operator to see a fire event and/or a fire threat, e.g., via the infrared portion of the multi-spectrum image, as well as locate the fire event/threat within the interior compartment 210, e.g., via the visible portion of the multi-spectrum image. Thus, aspects presented herein provide situational awareness of a fire event and/or threat in an interior compartment 210.

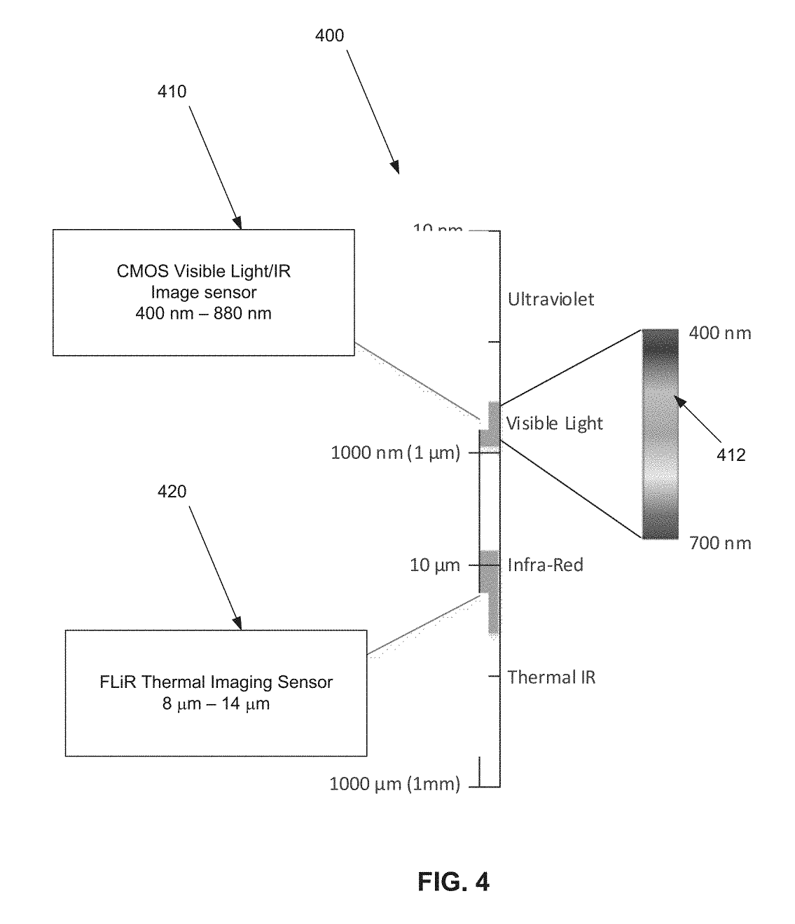

The image sensor circuitry 122 of fire detection system 120 is configured to optically monitor the interior compartment 210 for a fire event and/or threat by detecting radiation in multiple wavelength ranges at the same time, e.g., visible radiation within a visible light spectrum and thermal radiation within an infrared light spectrum. In exemplary aspects, image sensor circuitry 122 comprises multiple sensors, where one image sensor 122a is configured to detect a particular spectrum of radiation, e.g., the visible spectrum, while another image sensor 122b is configured to detect another spectrum of radiation, e.g., the infrared spectrum. FIG. 4 shows an electromagnetic spectrum 400 demonstrating the range of wavelengths for exemplary visible and infrared light spectrums, including a visible/infrared light spectrum 410, visible light spectrum 412, and infrared light spectrum 420. As shown in FIG. 4, the visible light spectrum 412 includes at least wavelengths ranging between 400 nm and 700 nm, and the infrared light spectrum 420 includes at least wavelengths ranging between 8,000 nm and 14,000 nm. In one exemplary aspect, image sensor 122a comprises a pinhole sensor, which detects visible light radiation in the visible light spectrum. Exemplary pinhole sensors typically include an infrared filter. Thus, removal of such a filter enables the pinhole sensor to detect wavelengths in a visible/infrared spectrum 410, e.g., between 400 nm and 880 nm. Examples of the image sensor 122a include, but are not limited to, the Omnivision 5647 Complementary Metal-Oxide-Semiconductorr (CMOS) Visible Light/IR image sensor, which generally detects radiation in the 400 nm to 700 nm range with the infrared filter, and detects radiation in the 400 nm to 880 nm range when the infrared filter is removed. In one exemplary aspect, image sensor 122b comprises a forward looking infrared (FLiR) sensor, which detects thermal radiation in the infrared light spectrum. Examples of image sensor 122b include, but are not limited to, the FLiR Lepton®—Thermal Imaging Sensor, which detects radiation in the 8,000 nm to 14,000 nm range.

The processor circuitry 124 of the fire detection system 120, which is communicatively coupled to the image sensor circuitry 122, processes the outputs from the image sensor circuitry 122 to generate the multi-spectrum image of the interior compartment 210. In particular aspects presented herein, the processor circuitry 124 combines the visible and infrared radiation detected by the image sensor circuitry 122 to generate the multi-spectrum image. For example, the processor circuitry 124 can combine the visible and infrared radiation using a sensor fusion technique that blends the detected radiation into one image containing pertinent information from both image sensors 122a, 122b. The processor circuitry 124 then outputs the multi-spectrum image to at least one operator terminal 130 via the network 110.

According to aspects of the disclosure, the processor circuitry 124 comprises one or more microprocessors, microcontrollers, hardware circuits, discrete logic circuits, hardware registers, digital signal processors (DSPs), field-programmable gate arrays (FPGAs), application-specific integrated circuits (ASICs), memory, or a combination thereof. In one such aspect, the processor circuitry 124 includes programmable hardware capable of executing software instructions stored, e.g., in memory 126 as a machine-readable computer program. Aspects of memory 126 include any non-transitory machine-readable media known in the art or that can be developed, whether volatile or non-volatile, including (but not limited to) solid state media (e.g., Static Random Access Memory (SRAM), Dynamic RAM (DRAM), Double Data RAM (DDRAM), Read Only Memory (ROM), Programmable ROM (PROM), Erasable PROM (EPROM), flash memory, solid state drive, etc.), removable storage devices (e.g., Secure Digital (SD) card, miniSD card, microSD card, memory stick, thumb-drive, Universal Serial Bus (USB) flash drive, ROM cartridge, Universal Media Disc), fixed drive (e.g., magnetic hard disk drive), or the like, individually or in any combination.

As noted herein, the processor circuitry 124 outputs the multi-spectrum image to at least one operator terminal 130 via network 110, e.g., to the display 132 and/or alarm circuitry 138 of the operator terminal 130. In one exemplary aspect, the display 132 displays the multi-spectrum image in a manner conspicuous to an operator, e.g., the crew of the aircraft and/or ground crew at the ground station. Examples of a display 132 according to various aspects herein include a telltale, an annunciator panel, a multi-function display (MFD), a touchscreen display, a Liquid Crystal Display (LCD), and/or a Light Emitting Diode (LED) display.

In some aspects, the processor circuitry 124 also outputs at least one of the individually detected visible and thermal radiation images, in addition to the multi-spectrum image, to the operator terminal 130. This exemplary option can provide an operator with additional details less visible/apparent in the multi-spectrum image, which ultimately will improve the accuracy of any threat assessment. It will be appreciated that the additional images of the visible and/or infrared radiation can be still images or videos, and that they are not required to have the same format as each other or as the multi-spectrum image. It will further be appreciated that display 132 can display the output images in any known fashion. In one aspect, display 132 can sequentially display multiple multi-spectrum images from multiple interior compartments 210. In one aspect, display 132 can sequentially display the multi-spectrum image, visible radiation image, and/or thermal radiation image from a single interior compartment 210 and/or multiple interior compartments 210. In one aspect, display 132 can simultaneously display multiple ones of the images, e.g., multiple multi-spectrum images from multiple interior compartments 210, or the multi-spectrum image, the visible radiation image, and/or the thermal radiation image from one or more interior compartments 210. In one exemplary aspect, display 132 comprises a single display 132, where the operator uses input circuitry 136 to control the display 132, e.g., to select a multi-spectrum image for a particular interior compartment 210, to scan through the multi-spectrum images for each of the monitored interior compartments 210, etc. Alternatively or additionally, processor circuitry 124 can control which multi-spectrum image is displayed on display 132, e.g., responsive to determining that a particular interior compartment 210 has an urgent fire event/threat. Alternatively, display 132 can comprise a plurality of displays, each associated with at least one fire detection system 120. It will further be appreciated that processor circuitry 124 can also provide additional information associated with the collection and/or creation of the images, e.g., the time span associated with the images, a zoom setting for the sensors, etc., one or more of which can also be displayed by display(s) 132.

In some aspects, the processor circuitry 124 further processes the multi-spectrum image to provide additional information to the operator terminal 130, e.g., a warning, alert, alarm, etc. To that end, the processor circuitry 124 processes the multi-spectrum image to determine a status of a fire event or threat in the interior compartment 210. For example, the processor circuitry 124 can determine whether any portion of the infrared light spectrum of the multi-spectrum image exceeds a fire threshold and/or whether a potential fire threat is located in high risk area of the interior compartment 210. Upon detection of such a threat, e.g., when the fire threshold is exceeded and/or when the fire is located in a high risk area, the processor circuitry 124 can be configured to output an alarm signal to the operator terminal 130, causing the operator terminal 130 to output a visible alarm (via display 132 and/or alarm circuitry 138) and/or an audible alarm (via alarm circuitry 138).

Using at least the multi-spectrum image provided by the operator terminal 130, and in some aspects, the individually detected visible and/or infrared radiation images and/or the audible/visible alarms, an operator is able to monitor the interior compartment 210 for a fire event and/or a fire threat. The generated multi-spectrum image provides significantly more information than typically provided by smoke detectors or basic fire detectors. For example, the infrared portion of the multi-spectrum image enables one or more operators viewing the multi-spectrum image to see heat signature of the interior compartment 210 (within the field of view of the image sensor 122b), which enables the operator(s) to assess the risk of any potential fire threat or fire event, as well as the intensity of any actual fire event. Further, the visible radiation portion of the multi-spectrum image enables the operator(s) to see the entire interior compartment 210 (within the field of view of the image sensor 122a), and thus enables the operator to more accurately determine the location of any potential fire event/threat, e.g., the location of any heat signatures of concern and/or the location of the fire, within the interior compartment 210. Operators evaluating the provided information can then make informed decisions regarding the risks of any fire event/threat, as well as informed decisions regarding the appropriate plan of action for responding to the fire event/threat.

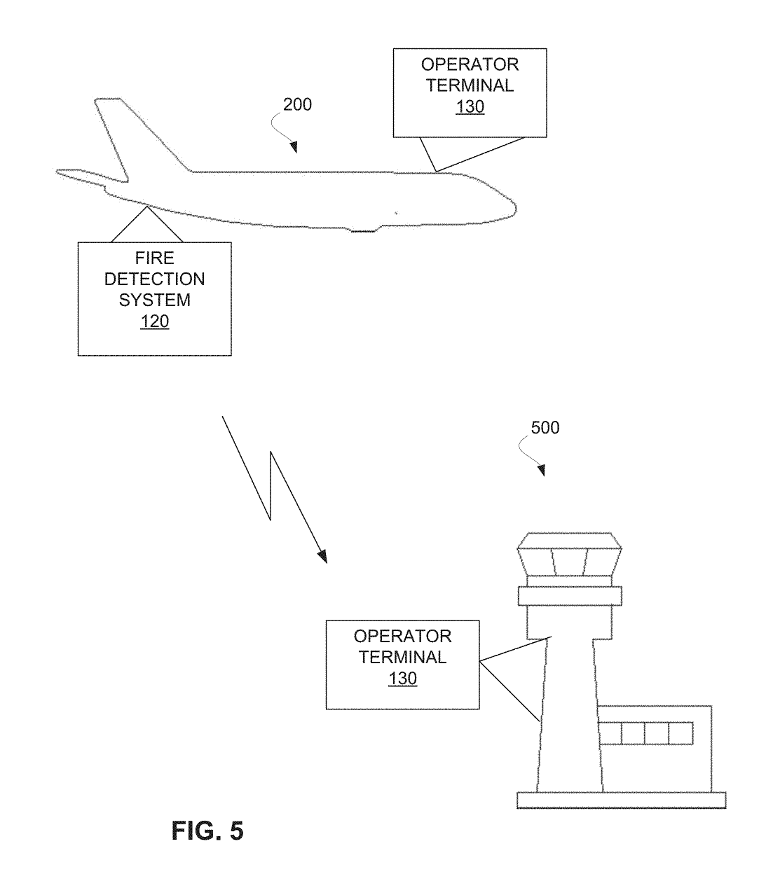

In some aspects, fire detection system 120 is part of an aircraft 200, as shown in FIG. 5. In particular aspects, the operator terminal 130 can also be part of the aircraft 200, e.g., in the cockpit 210e, which enables the crew to monitor one or more interior compartments 210 of the aircraft 200 for signs of a fire or fire threat. Alternatively or additionally, the operator terminal 130 can be part of a ground station 500 in communication with the aircraft 200, which enables ground control personnel to monitor the interior compartment(s) 210 of the aircraft 200 for signs of a fire or fire threat, which enables the ground control personnel to alert the aircraft crew and/or prepare for an emergency event that can be a result of the fire event/threat. The extensive amount of information provided by the multi-spectrum image (e.g., the location, size, and/or intensity of the fire) enables any operators viewing the multi-spectrum image to more accurately and swiftly asses any potential fire event/threat, which enables such operators to more efficiently develop an appropriate plan of action.

In some aspects, operator terminal 130 further includes input circuitry 136 for accepting input from an operator (e.g., a pilot). In some aspects, the operator can use the input circuitry 136 to control image sensor circuitry 122, e.g., to control a zoom and/or scan function of the image sensor circuitry 122 and/or select the time or time span of the multi-spectrum image. Alternatively or additionally, the operator can use the input circuitry 136 to control processor circuitry 124 and/or display 132 or alarm circuitry 138, e.g., to deactivate an alarm, to request particular images, e.g., video over a particular range of time, a still image at a particular point in time, only the multi-spectrum image, only images of the visible radiation, only images of the infrared radiation, and/or some combination thereof. According to particular aspects, the input circuitry 136 includes one or more of: a pointing device (e.g., a mouse, stylus, touchpad, trackball, pointing stick, joystick), a microphone (e.g., for speech input), an optical sensor (e.g., for optical recognition of gestures), and/or push keys (e.g., a keyboard, number-pad, and/or function keys). According to particular aspects of the present disclosure, the input circuitry 136 is implemented as a unitary physical component, or as a plurality of physical components that are contiguously or separately arranged, any of which may be communicatively coupled to any other, or may communicate with any other via an appropriate signaling medium (e.g., network 110).

In a further aspect, the processor circuitry 124 can be further configured to receive a warning suppression signal from the operator terminal 130, and in response, refrain from sending a further warning and/or multi-spectrum image to the operator terminal 130 until the processor circuitry 124 determines that the fire is no longer present and/or determines that a new fire threat is present in the same or a new interior compartment 210. For example, the warning suppression signal can be triggered via the input circuitry 136 of the operator terminal 130 by an operator of the aircraft 200 who has determined that the fire warning is the result of a false positive and wishes to prevent being further distracted by a corresponding notification on the display 132 and/or alarm circuitry 138.

In further aspects, the transceiver 134 of one operator terminal 130 can receive communications from another operator terminal 130, e.g., to obtain further information from the fire detection system 120, to suppress alarm signals, etc. Those skilled in the art will thus appreciate that the operator terminal(s) 130 and fire detection system(s) 120 of some aspects work together, sometimes along with input from the operator(s), to facilitate timely fire detection and response for a fire event in an interior compartment 210.

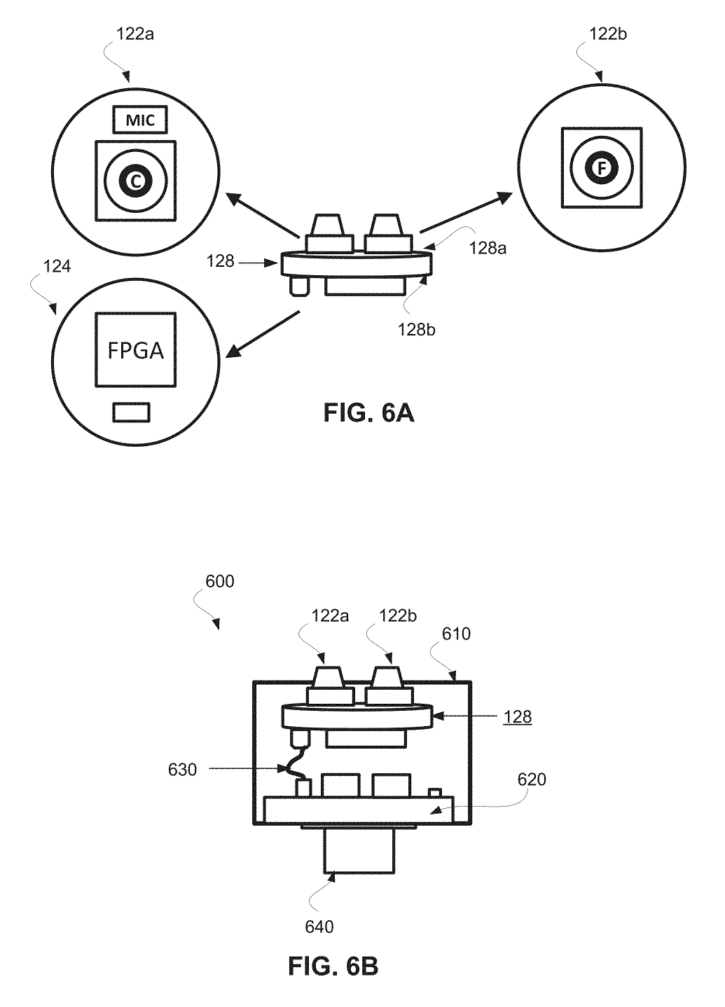

FIGS. 6A and 6B show exemplary aspects of the fire detection system 120 disclosed herein. Those skilled in the art will appreciate that these aspects are exemplary, and should not be construed as limiting. According to one exemplary aspect, the image sensor circuitry 122 and processor circuitry 124 are disposed on opposing sides of a printed circuit board (PCB) 128, as shown in FIG. 6A. In this exemplary aspect, the image sensor circuitry 122 comprises a pinhole Charge-Coupled Device (CCD) image sensor and an FLiR image sensor disposed on a first side 128a of the PCB 128, while the processor circuitry 124 (as well as a PCB interface connector, not shown) is disposed on the other side 128b of the PCB 128. FIG. 6B shows the fire detection system as part of a camera board stack-up 600, where the fire detection system 120 is disposed in an enclosure/camera housing 610 such that at least the lens portions of the image sensors 122a, 122b extend outwardly from the housing 610 while the rest of the fire detection system is enclosed within the housing 610. Housing 610 also includes an interface board 620 for the power supply, which operatively connects to the fire detection system via one or more wires 630 and to a power interface connector 640. The power interface connector 640 extends outwardly from the housing 610 to enable a power supply to be connected to the fire detection system 120, and in some aspects, to connect the fire detection system 120 to the network 110. In some aspects, the exemplary aspects enable the fire detection system 120 disclosed herein to be a plug-n-play replacement for existing camera systems, e.g., 802.3a Power over Ethernet (PoE) compliant cameras currently installed on aircraft 200, e.g., the 777-9X aircraft. Such PoE compliance will also facilitate the use of the fire detection system 120 disclosed herein in non-aircraft environments.

Aspects presented herein are described in terms of at least one fire detection system 120 in each interior compartment 210. It will be appreciated that while each interior compartment 210 necessarily includes at least one image sensor circuitry 122, processor circuitry 124 can be associated with multiple image sensor circuitry 122 located in the same or in different interior compartments 210. For example, an interior compartment 210 can include multiple image sensor circuitry 122, e.g., in different locations in the interior compartment 210 and/or pointed at different locations of the interior compartment 210, where each image sensor circuitry 122 operatively connects to a common processor circuitry 124. Alternatively or additionally, a common processor circuitry 124 can be operatively connected to multiple image sensor circuitry 122, each located in different interior compartments 210.

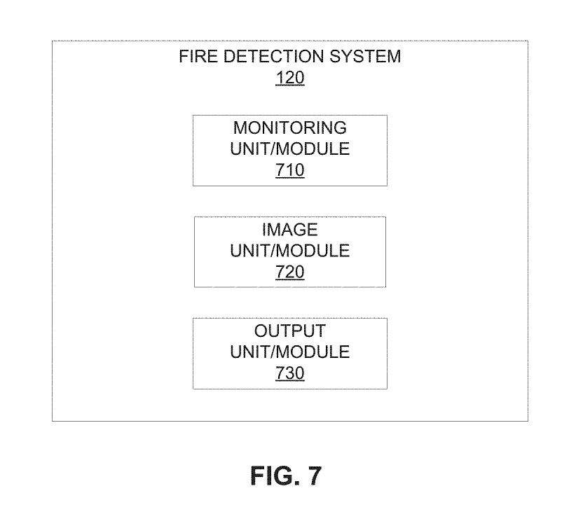

Aspects of the present disclosure further include the fire detection system 120 implemented according to the hardware units and/or software modules illustrated in FIG. 7 (e.g., as components of the processor circuitry 124, components of the image sensor circuitry 122, and/or instructions stored in the memory 126, as shown in FIG. 1). The fire detection system 120 shown in FIG. 7 comprises a monitoring unit and/or module 710, an image unit and/or module 720, and an output unit and/or module 730. The monitoring unit and/or module 710 is configured to optically monitor an interior compartment 210 by detecting visible radiation in a visible light spectrum at a first time and thermal radiation in an infrared light spectrum at the first time using image sensor circuitry 122 mounted inside the interior compartment 210. The image unit and/or module 720 is configured to process the detected radiation by combining the visible and thermal radiation to generate a multi-spectrum image of the interior compartment 210. The output unit and/or module 730 is configured to output at least the multi-spectrum image to an operator terminal 130.

Aspects of the present disclosure further include various methods and processes, as described herein, implemented using various hardware configurations configured in ways that vary in certain details from the broad descriptions given above. For instance, one or more of the processing functionalities discussed above may be implemented using a general-purpose microprocessor configured with program instructions rather than dedicated hardware, depending on, e.g., the design and cost tradeoffs for the various approaches, and/or system-level requirements outside the scope of the present disclosure.

Indeed, aspects of the present disclosure can, of course, be carried out in other ways than those specifically set forth herein without departing from the essential characteristics therefrom. The aspects disclosed herein are to be considered in all respects as illustrative and not restrictive, and all changes coming within the meaning and equivalency range of the appended claims are intended to be embraced therein. In particular, although steps of particular processes or methods described herein are shown and described as being in a particular sequence or temporal order, the steps of any such processes or methods are not limited to being carried out in any particular sequence or order, absent an indication otherwise. Indeed, the steps in such processes or methods are generally carried out in various different sequences and orders according to particular aspects of the present disclosure while still falling within the scope of the present disclosure.

1. A method of generating a multi-spectrum image of an interior compartment for fire detection within the interior compartment, the method comprising:
optically monitoring the interior compartment using image sensor circuitry comprising separate first and second image sensors, said first image sensor configured to detect visible radiation within a visible light spectrum at a first time and said second image sensor configured to detect thermal radiation within an infrared light spectrum at the first time;
generating the multi-spectrum image of the interior compartment at the first time by combining the detected visible radiation with the detected thermal radiation; and
outputting the multi-spectrum image to at least one operator terminal.

2. (canceled)

3. The method of claim 1 wherein the first image sensor comprises a pinhole image sensor and the second image sensor comprises a forward looking infrared image sensor.

4. The method of claim 1 further comprising detecting, using the first image sensor, additional thermal radiation within an additional infrared light spectrum at the first time in combination with the visible radiation within the visible light spectrum detected at the first time, wherein generating the multi-spectrum image comprises combining the detected thermal radiation output by the second image sensor with the visible radiation in combination with the additional thermal radiation output by the first image sensor.

5. The method of claim 1 wherein the interior compartment is comprised within an aircraft, and wherein the at least one operator terminal is comprised within a cockpit of the aircraft.

6. The method of claim 5 wherein the aircraft is in wireless communication with a ground station, and wherein outputting the multi-spectrum signal to the at least one operator terminal further comprises transmitting the multi-spectrum image to an operator terminal in the ground station.

7. The method of claim 1 further comprising:
processing the multi-spectrum image to determine a fire status of the interior compartment; and
upon detection of a fire event within the interior compartment responsive to the processing of the multi-spectrum image, outputting an alarm signal to the at least one operator terminal to provide at least one of a visible alarm and an audio alarm at the operator terminal.

8. The method of claim 1 further comprising outputting at least one of the detected visible radiation and the detected thermal radiation to the at least one operator terminal.

9. The method of claim 1 wherein the visible light spectrum includes at least wavelengths ranging between 400 nm and 700 nm, and wherein the infrared light spectrum includes at least wavelengths ranging between 8,000 nm and 14,000 nm.

10. A fire detection system configured to generate a multi-spectrum image of an interior compartment to facilitate fire detection within the interior compartment, the fire detection system comprising:
image sensor circuitry comprising separate first and second image sensors configured to optically monitor the interior compartment, said first image sensor configured to detect visible radiation within a visible light spectrum at a first time and said second image sensor configured to detect thermal radiation within an infrared light spectrum at the first time;
processor circuitry operatively connected to the image sensor circuitry, said processor circuitry configured to:
generate the multi-spectrum image of the interior compartment at the first time by combining the detected visible radiation with the detected thermal radiation; and
output the multi-spectrum image to at least one operator terminal communicatively coupled to the processor circuitry.

11. (canceled)

12. The fire detection system of claim 10 wherein the first image sensor comprises a pinhole image sensor and the second image sensor comprises a forward looking infrared image sensor, wherein the pinhole image sensor and the forward looking infrared image sensor are disposed on a first side of a printed circuit board, and the processor circuitry are disposed on a second side of the printed circuit board, said first and second sides on opposing sides of the printed circuit board.

13. The fire detection system of claim 10 wherein the first image sensor is further configured to detect additional thermal radiation within an additional infrared light spectrum at the first time in combination with the visible radiation within the visible light spectrum detected at the first time, wherein the processor circuitry generates the multi-spectrum image by combining the detected thermal radiation output by the second image sensor with the detected visible radiation in combination with the additional thermal radiation output by the first image sensor.

14. The fire detection system of claim 10, wherein the interior compartment is comprised within an aircraft, and wherein the at least one operator terminal is comprised within a cockpit of the aircraft.

15. The fire detection system of claim 14, wherein the aircraft is in wireless communication with a ground station, and wherein the processor circuitry is further configured to output the multi-spectrum image by transmitting the multi-spectrum image to an operator terminal in the ground station.

16. The fire detection system of claim 10, wherein the processor circuitry is further configured to:
process the multi-spectrum image to determine a fire status of the interior compartment; and
upon detection of a fire event within the interior compartment responsive to the processing of the multi-spectrum image, output an alarm signal to the at least one operator terminal to provide at least one of a visible alarm and an audio alarm to the at least one operator terminal.

17. The fire detection system of claim 10 wherein the processor circuitry is further configured to output at least one of the detected visible radiation and the detected thermal radiation to the at least one operator terminal.

18. The fire detection system of claim 10 wherein visible radiation and the thermal radiation each comprise still images captured at the first time or a video comprising a sequence of images captured at the first time.

19. The fire detection system of claim 10 wherein the visible light spectrum includes at least wavelengths between 400 nm and 700 nm, and wherein the infrared light spectrum includes at least wavelengths ranging between 8,000 nm and 14,000 nm.

20. A non-transitory computer readable medium storing a computer program product for controlling a programmable fire detection system to generate a multi-spectrum image of an interior compartment to facilitate fire detection within the interior compartment, the computer program product comprising software instruction that, when executed on processor circuitry of the programmable fire detection system, causes the processor circuitry to:
optically monitor the interior compartment using image sensor circuitry comprising separate first and second image sensors, said first image sensor configured to detect visible radiation within a visible light spectrum at a first time and said second image sensor configured to detect thermal radiation within an infrared light spectrum at the first time;
generate the multi-spectrum image of the interior compartment at the first time by combining the detected visible radiation with the detected thermal radiation; and
output the multi-spectrum image to at least one operator terminal.
